(19) United States
(12) Patent Application Publication
(10) Pub. No.: US 2009/0127639 A1
(43) Pub. Date: May 21, 2009

(54) SEMICONDUCTOR APPARATUS

(75) Inventors: Kazuhiro Suzuki, Tokyo (JP); Yoshinori Iida, Tokyo (JP); Hideyuki Funaki, Tokyo (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/206,101

(22) Filed: Sep. 8, 2008

(30) Foreign Application Priority Data
Sep. 21, 2007 (JP) 2007-245145

(51) Int. Cl. H01L 25/00

(52) U.S. Cl. 257/415; 257/778; 73/514.29; 257/E25.001

(57) ABSTRACT

A semiconductor apparatus includes: a first chip including a MEMS device which has a structure supported in midair therein, and having first pads and a first joining region electrically connected to the MEMS device on a top face thereof; a second chip including a circuit having a semiconductor device electrically connected to the MEMS device therein, and having second pads and a second joining region electrically connected to the semiconductor device on a top face thereof, the second chip being disposed in opposition to the first chip so as to oppose the second pads and the second joining region respectively to the first pads and the first joining region; electrical connection parts which electrically connect the first pads to the second pads, respectively; and joining parts provided between the first joining region and the second joining region opposed to the first joining region to join the first chip and the second chip to each other.

### CROSS-REFERENCE TO RELATED APPLICATION

This application is based upon and claims the benefit of priority from prior Japanese Patent Application No. 2007-245145 filed on Sep. 21, 2007 in Japan, the entire contents of which are incorporated herein by reference.

### BACKGROUND OF THE INVENTION

1. Field of the Invention

The present invention relates to a semiconductor apparatus obtained by mounting a microelectronics mechanical system (hereafter referred to simply as “MEMS”) which is a mixture of a sensor or actuator (mechanical drive mechanism) and an integrated circuit for driving the sensor or actuator on a substrate.

2. Related Art

In a semiconductor apparatus manufactured by utilizing a semiconductor manufacture technique, it is easy to implement a higher function and higher performance. At the present time, sensors and actuators using various MEMS techniques are commercialized and function systems are provided. Here, it is necessary to connect a MEMS which conducts mechanical operation to an integrated circuit which controls the MEMS and incorporate them into a module. In a scheme adopted heretofore, the MEMS and the control IC are packaged individually and finally electrical connection is conducted. In recent years, however, system products have been made smaller-sized and thinner, and a smaller size is required of the module including the MEMS and the control IC.

A MEMS sensor suitable for an acoustic sensor such as a microphone is disclosed in JP-A 2007-124500 (KOKAI). According to a technique disclosed in JP-A 2007-124500 (KOKAI), a MEMS sensor chip and a circuit chip are arranged in the lateral direction on a circuit substrate and connected by using a bonding wire. Furthermore, a system incorporating them is sealed by using a metal cap.

A technique of turning the MEMS chip over with respect to a package part, mounting both of them, and then sealing them is disclosed in JP-A 2007-136668 (KOKAI). And leads are pulled out to the package part to interface with a desired control circuit.

In a semiconductor apparatus including a MEMS chip, the MEMS chip has a hollow structure as described in JP-A 2007-124500 (KOKAI) and JP-A 2007-136668 (KOKAI). Unlike the typical LSI, therefore, it is necessary to cover the top to protect against disturbance and conduct packaging.

In a semiconductor apparatus which often assumes the multi-chip configuration, mainly a MEMS part, a control IC part, and a cap part are combined and mounted. Since individual members are combined, therefore, the dimension in the horizontal direction or vertical direction becomes large, resulting in an increase of the system size. For example, bonding wires are used in the interface between the MEMS and the control IC. In this case, however, the wiring length becomes long, resulting in lowering of the system performance.

### SUMMARY OF THE INVENTION

The present invention has been made in view of these circumstances, and an object thereof is to provide a semiconductor apparatus capable of suppressing the increase of the mounting volume as much as possible and suppressing the lowering of the performance as much as possible.

A semiconductor apparatus according to an aspect of the present invention includes: a first chip including a MEMS device which has a structure supported in midair therein, and having first pads and a first joining region electrically connected to the MEMS device on a top face thereof; a second chip including a circuit having a semiconductor device electrically connected to the MEMS device therein, and having second pads and a second joining region electrically connected to the semiconductor device on a top face thereof, the second chip being disposed in opposition to the first chip so as to oppose the second pads and the second joining region respectively to the first pads and the first joining region; electrical connection parts which electrically connect the first pads to the second pads, respectively; and joining parts provided between the first joining region and the second joining region opposed to the first joining region to join the first chip and the second chip to each other.

### BRIEF DESCRIPTION OF THE DRAWINGS

FIG. 1 is a sectional view of a semiconductor apparatus according to an embodiment of the present invention;

FIG. 2 is an oblique view showing a state of a semiconductor apparatus according to an embodiment, obtained immediately before joining;

FIG. 3 is a diagram for explaining another scheme of joining;

FIG. 4 is a plan view of a semiconductor chip in an embodiment;

FIGS. 5A to 5C are sectional views showing manufacturing processes of a semiconductor chip according to an embodiment;

FIGS. 6A to 6C are sectional views showing manufacturing processes of a MEMS chip according to an embodiment;

FIG. 7 is a sectional view showing a manufacturing process of a semiconductor apparatus according to an embodiment;

FIG. 8 is a sectional view of a semiconductor apparatus in a first example;

FIG. 9 is a sectional view of a semiconductor apparatus in the first example;

FIG. 10 is a sectional view of a semiconductor apparatus in a second example; and

FIGS. 11A and 11B are diagrams for explaining another method for conducting joining with a wafer scale to obtain a semiconductor apparatus.

### DETAILED DESCRIPTION OF THE INVENTION

Hereafter, embodiments of the present invention will be described with reference to the drawings. By the way, in the ensuing description of the drawings, the same or similar parts are denoted by the same or similar characters. However, it is to be noted that the drawings are schematic and relations between thicknesses and plane dimensions and ratios in thickness among layers are different from those in actuality. Therefore, concrete thicknesses and dimensions should be judged in consideration of the ensuing description. Furthermore, it is a matter of course that parts which differ in mutual dimension relation or ratio between drawings are included.

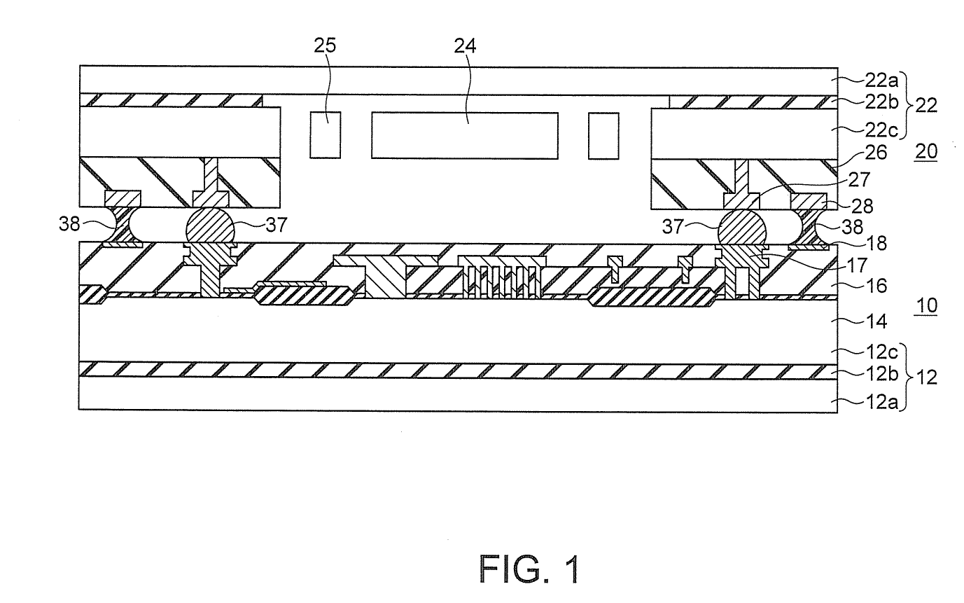

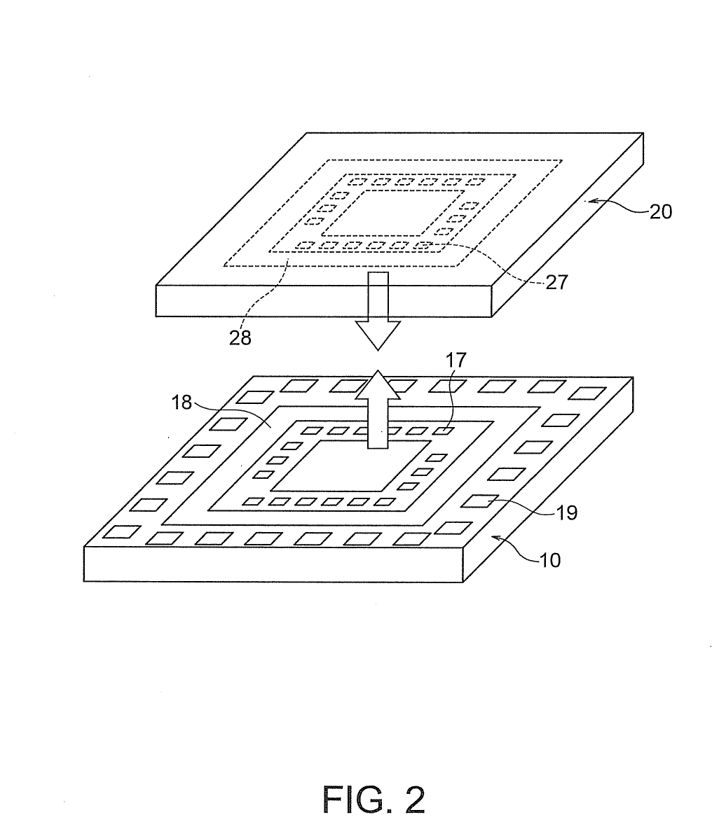

A semiconductor apparatus according to an embodiment of the present invention is shown in FIGS. 1 and 2. FIG. 1 is a sectional view of the semiconductor apparatus according to the present embodiment. FIG. 2 is an oblique view showing a state of the semiconductor apparatus according to the present embodiment, obtained immediately before joining of a semiconductor chip to a MEMS chip.

The semiconductor apparatus according to the present embodiment includes a semiconductor chip 10 having a semiconductor device 14 formed therein and a MEMS chip 20 having a MEMS device 24 formed therein. The chips are arranged so as to oppose a plane on which the semiconductor device 14 in the semiconductor chip 10 is formed to a plane on which the MEMS device 24 in the MEMS chip 20 is formed. And the chips are joined by using sealing material 38 formed of a bonding agent or the like. The semiconductor device 14 is formed in a SOI (Silicon On Insulator) layer 12c of a SOI substrate 12 which includes a support substrate 12a, a buried insulation film 12b and the SOI layer 12c. The semiconductor device 14 is a control circuit which controls the MEMS device 24. An interlayer insulation film 16 is formed so as to cover the semiconductor device 14. Electrodes, contacts and wiring to be electrically connected to the semiconductor device 14 are formed in the interlayer insulation film 16. Pads 17 for electrical connection to the MEMS device 24 are provided on a region of a top face of the interlayer insulation film 16 surrounded by a joining region 18 on which the sealing material 38 is applied. The pads 17 are electrically connected to the semiconductor device 14 via contacts formed in the interlayer insulation film 16. External pullout pads 19 for electrical connection to the outside are provided on a region which is located on the top face of the interlayer insulation film 16 and which is located outside the region surrounded by the joining region 18.

On the other hand, the MEMS device 24 is formed in a SOI layer 22c of a SOI substrate 22 which includes a support substrate 22a, a buried insulation film 22b and the SOI layer 22c. The MEMS device 24 has a structure supported in the midair by a support part 25. The MEMS device 24 is electrically connected to a peripheral circuit (not illustrated) formed in the SOI layer 22c, via the support part 25. An interlayer insulation film 26 is formed so as to cover a region in which the peripheral circuit is formed. The interlayer insulation film 26 does not cover a region where the MEMS device 24 is formed. Electrodes, contacts and wiring to be electrically connected to the peripheral circuit are formed in the interlayer insulation film 26. Pads 27 for electrical connection to the semiconductor device 14 are provided on a region of a top face of the interlayer insulation film 26 surrounded by a joining region 28 on which the sealing material 38 is formed. The pads 27 are electrically connected to the pads 17 of the semiconductor chip 10 via metal bumps 37. By the way, the sealing material 38 is formed on the joining region 18 of the semiconductor chip 10 and the joining region 28 of the MEMS chip 20, and the semiconductor chip 10 and the MEMS chip 20 are joined to each other. Therefore, the MEMS device 24 is sealed in the region of the top face of the interlayer insulation film 26 surrounded by the sealing material 38.

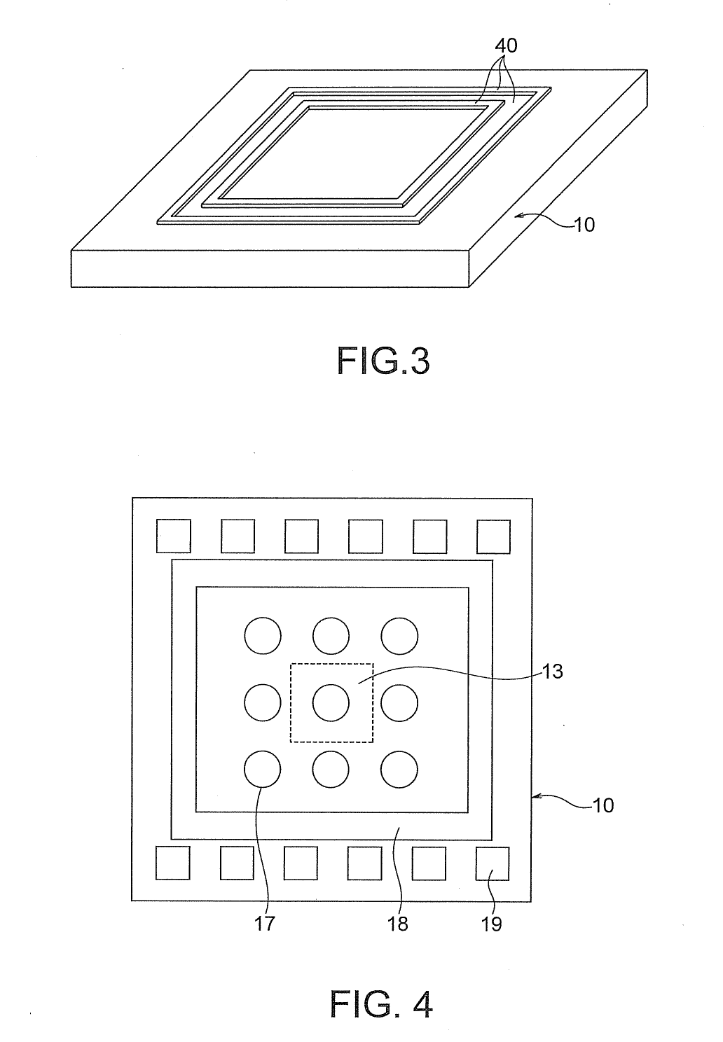

In the present embodiment, each of the semiconductor device and the MEMS device is formed on a SOI substrate. However, at least one of them may be formed on a bulk substrate. Furthermore, in the present embodiment, the semiconductor chip 10 and the MEMS chip 20 are joined to each other by using the seal material 38. As an alternative joining method, it is also possible to provide an uneven part 40 on the substrate of each chip and join the semiconductor chip 10 and the MEMS chip 20 to each other by using the uneven part 40. By the way, although only the semiconductor chip 10 is shown in FIG. 3, an uneven part which engages with the uneven part formed on the substrate of the semiconductor chip 10 is provided on the substrate of the MEMS chip 20 as well.

In the semiconductor chip 10 in the semiconductor device according to the present embodiment, a region 13 where the semiconductor device 14 is to be formed is disposed in the center of the chip. The pads 17 are disposed so as to surround the device forming region 13 in order to achieve electrical connection between the semiconductor device 14 and the MEMS device 24. In addition, the sealing joining part 18 is provided outside the pads 17 to join the semiconductor chip 10 and the MEMS chip 20 to each other.

Incidentally, in the present embodiment, electrical connection between the MEMS chip 20 and the semiconductor chip 10 is conducted by using the metal bumps 37. However, it is a matter of course that the electrical connection is not restricted to the metal bumps 37. As for the electrical connection, it is also possible to activate the topmost face of the substrate in a plasma environment, form uncombined hands, and join the chips directly in the vacuum. As for the seal joining part, a thermosetting resin such as polyimide or photoresist may be used, or a conductive material may be used.

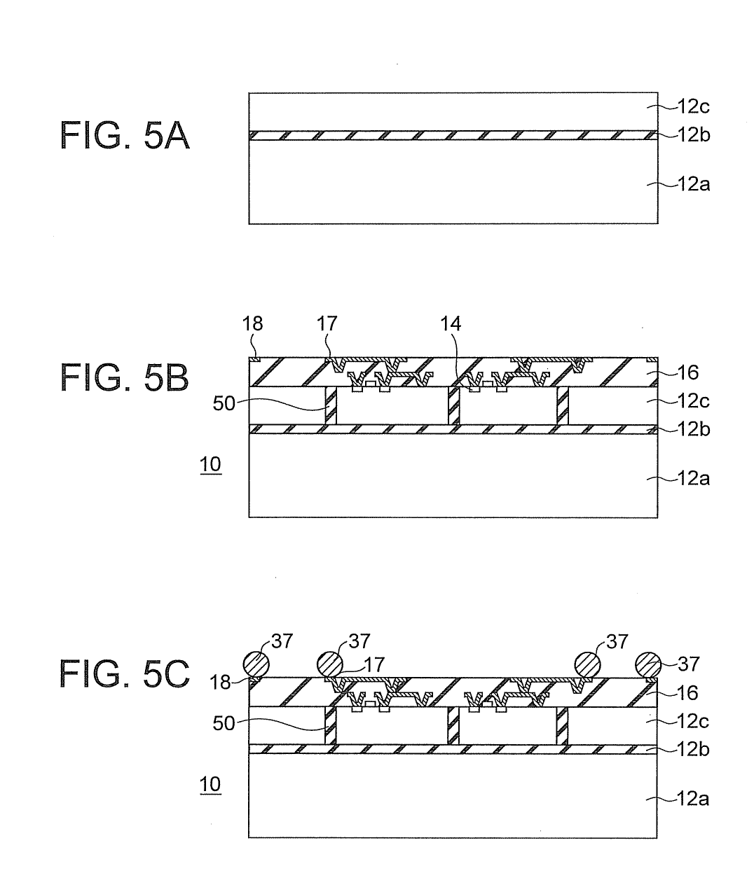

A method for manufacturing a semiconductor apparatus according to the present embodiment will now be described with reference to FIGS. 5A to 7.

First, as shown in FIG. 5A, the SOI substrate 12 in which the buried insulation film 12b is formed on the support substrate 12a and the SOI layer 12c is formed on the buried insulation film 12b is prepared. Thereafter, as shown in FIG. 5B, a plurality of element forming regions are formed in the SOI layer 12c by element isolation regions 50 and the semiconductor device 14 is formed in each of the element forming regions. Subsequently, the interlayer insulation film 16 covering these semiconductor devices 14 is formed, and the contacts, the wiring, the pads 17 and the joining region 18 for achieving electrical connection with the semiconductor devices 14 are formed in the interlayer insulation film 16 to complete the semiconductor chip 10 (see FIG. 5B). Thereafter, the metal bumps 37 are formed on the pads 17 of the interlayer insulation film 16 by using solder, and metal bumps 38a are applied to the joining region 18 (see FIG. 5C).

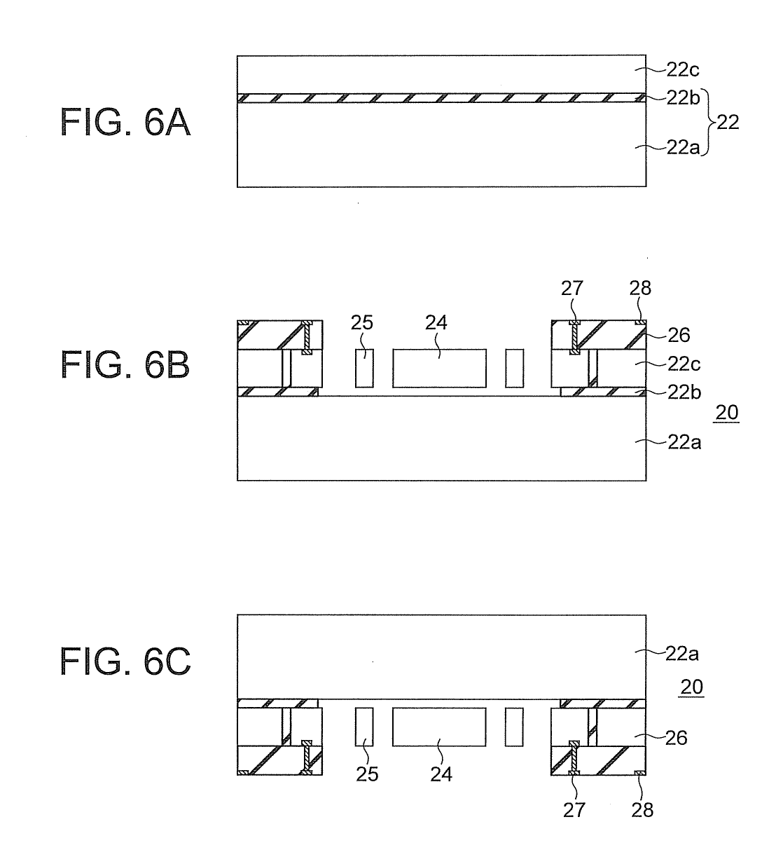

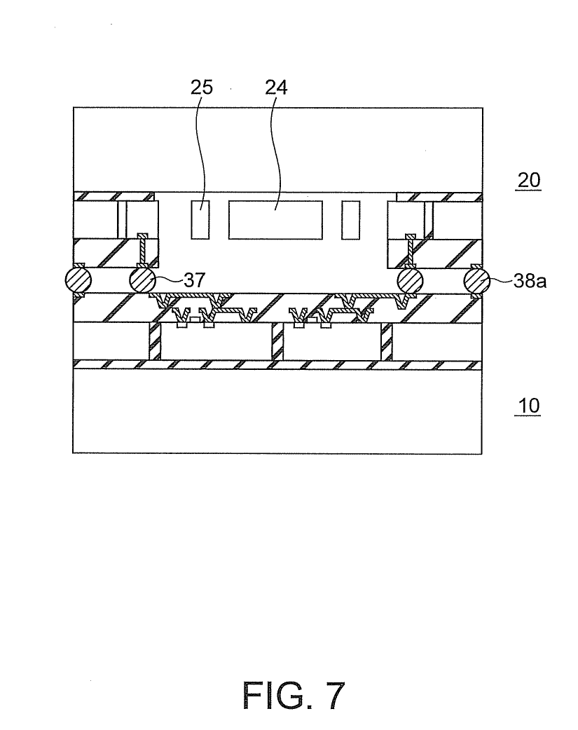

On the other hand, as shown in FIG. 6A, the SOI substrate 22 in which the buried insulation film 22b is formed on the support substrate 22a and the SOI layer 22c is formed on the buried insulation film 22b is prepared. Thereafter, as shown in FIG. 6B, the MEMS device 24 having a hollow structure and the support part 25 which supports the MEMS device 24 are formed in the SOI layer 22c, and the interlayer insulation film 26 is formed on a region of the SOI layer 22c where neither the MEMS device 24 nor the support part 25 is formed. Subsequently, the contacts, the wiring, the pads 27 and the joining region 28 for achieving electrical connection with the MEMS device 24 are formed in the interlayer insulation film 26 to complete the MEMS chip 20 (see FIG. 6B). Subsequently as shown in FIG. 6C, the MEMS chip 20 is vertically inverted, and the inverted MEMS chip 20 is aligned in position with the semiconductor chip 10 having the metal bumps 37 and the metal bumps 38a formed thereon and joined to the semiconductor chip 10 to complete the semiconductor apparatus (see FIG. 7). The joining may be conducted while applying pressure to both the semiconductor chip 10 and the MEMS chip 20 vertically.

The electrical joining parts (pads) 17 and 27 and the seal joining parts (joining regions) 18 and 28 of the semiconductor chip 10 and the MEMS chip 20 are formed by depositing a conductive material with sputtering or evaporation and patterning the conductive material. As the conductive material, Cu, Al, Ti or W, or a silicide or barrier metal obtained by combining them can be used. Here, it is necessary to make the height of the topmost part of the semiconductor chip 10 and the MEMS chip 20 uniform. For example, therefore, it is necessary to provide the peripheral interlayer insulation films 16 and 26 formed of TEOS, the patterned pads 17 and 27, and the joining regions 18 and 28 with the same height by using a planarization process such as the CMP.

In the manufacturing method, the metal bumps 37 and 38a are formed on the semiconductor chip. However, the metal bumps 37 and 38a may be formed on the MEMS chip 20 or may be formed on both the semiconductor chip 10 and the MEMS chip 20. As for the joining parts 38a, not only solder as described earlier, but also direct joining using surface activation or the thermosetting resin may be used.

Processes ranging from the position alignment between the semiconductor chip 10 and the MEMS chip 20 to the joining are conducted in a vacuum environment. As a result, it becomes possible to seal the MEMS device 24 which retains hollow regions above, below, and on the left and right side in the decompression state caused by evacuation. Accordingly, it also becomes possible to reduce the viscosity resistance of the hollow region. As a result, the Q value of the MEMS itself is improved and consequently the performance can be improved.

According to the present embodiment, the support substrate 22a of the SOI substrate having the MEMS device formed therein becomes a cap of the MEMS device as heretofore described and a protection part which protects the MEMS device becomes unnecessary. And direct electrical connection and sealing of the MEMS chip and the semiconductor chip are executed. As a result, the number of mounted parts and the mounting volume can be reduced. Furthermore, it becomes possible to shorten the electric wiring length, reduce noise caused by the wiring part, and improve the function of the system. As a result, a low cost, low size, high performance semiconductor apparatus can be obtained.

### FIRST EXAMPLE

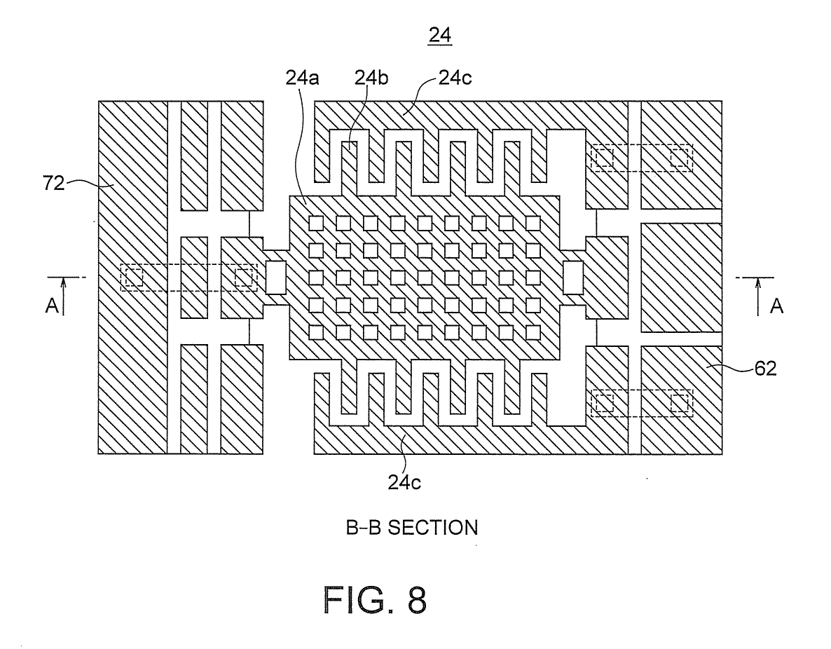

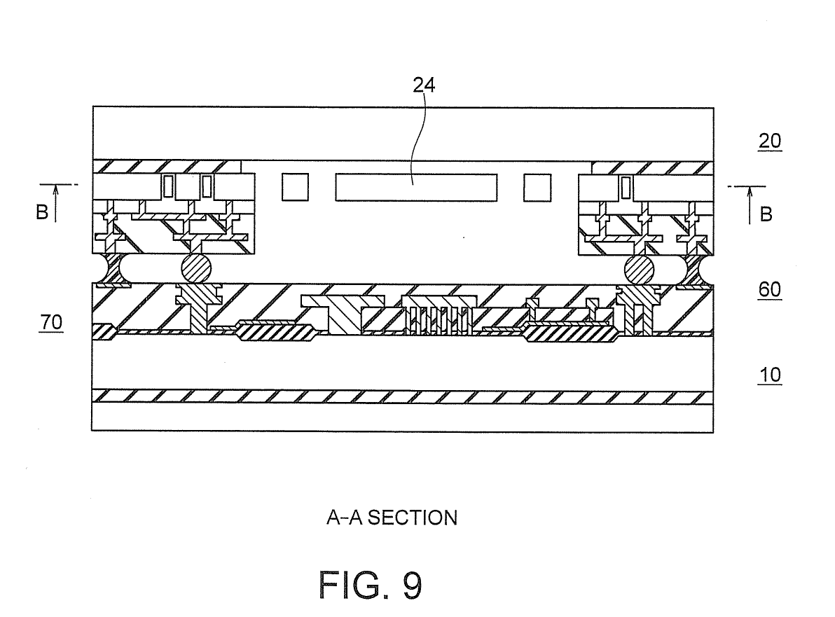

As a first example of the present invention, a semiconductor apparatus having a vibration type angular velocity sensor as the MEMS device 24 is shown in FIGS. 8 and 9. FIGS. 8 and 9 are sectional views of the semiconductor apparatus according to the present example. FIG. 8 shows a section obtained by cutting along a cut line B-B shown in FIG. 9. FIG. 9 shows a section obtained by cutting along a cut line A-A shown in FIG. 8.

A vibration type angular velocity sensor which detects the angular velocity from Coriolis force applied to a moving object is typically known as the device to which the MEMS technique is applied. The vibration type angular velocity sensor has a configuration which actively vibrates sensor mass and detects a change component of capacitance between the sensor mass and the substrate caused by a displacement of the sensor mass incurred by application of an angular velocity. In the present example, a vibration type angular velocity sensor 24 includes a sensor mass 24a, comb-shaped movable electrodes 24b connected to respective sides of the sensor mass 24a, and comb-shaped stationary electrodes 24c provided so as to be opposed to the movable electrodes 24b. A drive source for driving the vibration type angular velocity sensor 24 and signal processing of detecting the capacitance change and conducting signal amplification are needed. In the present example, a semiconductor apparatus with a sensor and a peripheral circuit united thereto can be obtained by forming a drive electrode 62 to drive the vibration type angular velocity sensor 24 and a detection electrode 72 to obtain a capacitance change on the MEMS chip 20, forming a drive circuit 60 and a detection circuit 70 respectively connected to the electrodes 62 and 72 electrically on the semiconductor chip 10, opposing and connecting the semiconductor chip 10 and the MEMS chip 20 to each other.

It is desired to increase the Coriolis force in raising the detection sensitivity of the angular velocity. In this case, it becomes possible to obtain larger Coriolis force as the motion velocity of the sensor increases. It can be achieved to drive the MEMS device fast by lowering the viscosity resistance of the environment in which the MEMS device is sealed, i.e., driving the MEMS device in the decompression state. In recent years, a technique of applying an ion beam to the surface of a chip, activating the surface, and joining chips directly at the normal temperature has been established. By applying this technique to the process of joining the semiconductor chip 10 and the MEMS chip 20 in the semiconductor apparatus according to the present example, sealing of the MEMS angular velocity sensor 24 and electrical joining can be executed in the vacuum environment and the performance of the sensor can be improved. Furthermore, an extra dead space can be excluded and it can be made possible to reduce the cost and size of the sensor system by connecting and opposing the sensor and an associated circuit part to each other.

### SECOND EXAMPLE

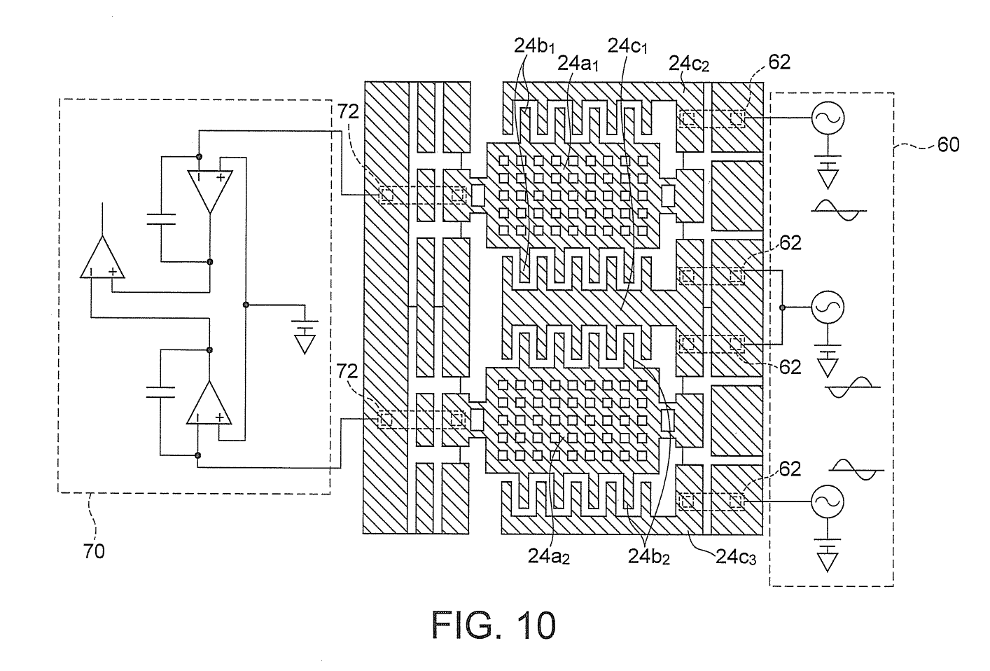

A semiconductor apparatus according to a second example is shown in FIG. 10. In the semiconductor apparatus according to the present example, the MEMS device is a vibration type angular velocity sensor. Its sectional view corresponding to FIG. 8 for the first example is shown in FIG. 10. In the present example, the MEMS device includes two angular velocity sensors described with reference to the first example. In other words, the MEMS device includes two sensor masses 24a₁ and 24a₂, comb-shaped movable electrodes 24b₁ connected to respective sides of the sensor mass 24a₁, comb-shaped movable electrodes 24b₂ connected to respective sides of the sensor mass 24a₂, a common comb-shaped stationary electrode 24c₁ provided between the sensor masses 24a₁ and 24a₂, a comb-shaped stationary electrode 24c₂ provided on an opposite side of the sensor mass 24a₁, and a comb-shaped stationary electrode 24c₃ provided on an opposite side of the sensor mass 24a₂ from the stationary electrode 24c₁.

In the present example, AC signals having opposite phases are applied respectively to the two angular velocity sensors as drive signals from a drive circuit 60. At this time, a detection circuit 70 detects a displacement of the sensor mass of each of the angular velocity sensors as a change of capacitance between the sensor mass and the substrate, and outputs a difference between them.

It is desirable to seal the angular velocity sensors in the second example as well in the same way as the angular velocity sensor in the first example.

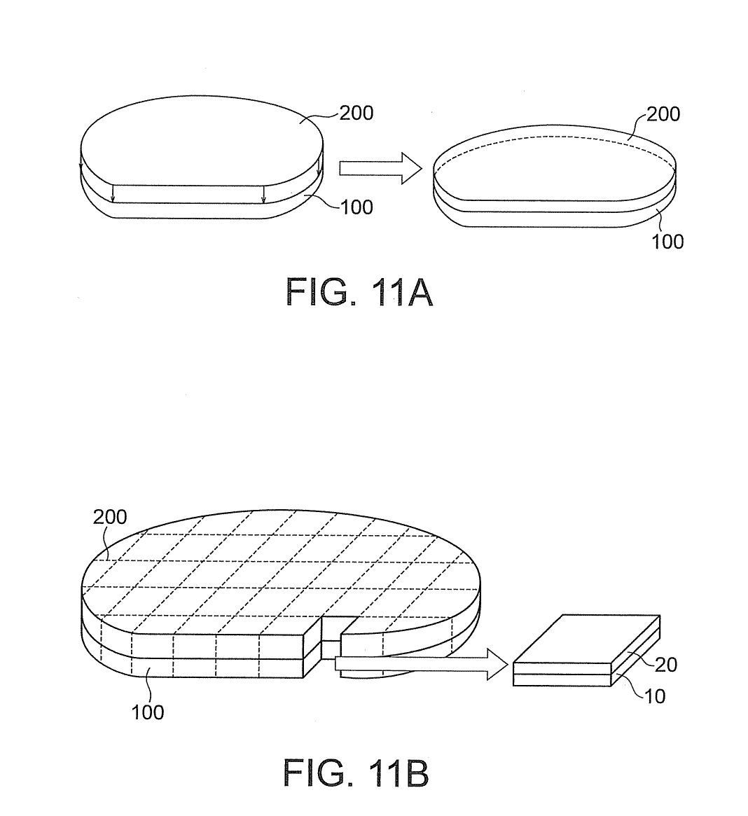

In the embodiments and examples, joining is conducted at the chip level. If technique of applying an ion beam to the surface of a chip, activating the surface, and joining chips directly at the normal temperature is used, however, it becomes possible to directly join a semiconductor wafer 100 having a plurality of semiconductor devices formed thereon and a MEMS wafer 200 having a plurality of MEMS devices formed thereon as shown in FIG. 11A. It also becomes possible to conduct dicing to the chip scale thereafter as shown in FIG. 11B.

Heretofore, individualization has been a great problem in forming MEMS devices. When individualizing MEMS devices having the hollow structure, it is difficult to use typical dicing because of device destruction caused by influence of water, and low stress dicing using laser light or the like is needed. If the joining scheme described with reference to FIGS. 11A and 11B is used, then joining which is high in airtightness at, for example, the wafer level and firm becomes possible. Even if the general purpose blade type dicing is applied, therefore, it is possible to avoid destruction of the MEMS devices.

According to the embodiments of the present invention, it is possible to suppress the increase of the mounting volume as much as possible and suppress the lowering of the performance as much as possible.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor apparatus comprising:
a first chip including a MEMS device which has a structure supported in midair therein, and having first pads and a first joining region electrically connected to the MEMS device on a top face thereof;
a second chip including a circuit having a semiconductor device electrically connected to the MEMS device therein, and having second pads and a second joining region electrically connected to the semiconductor device on a top face thereof, the second chip being disposed in opposition to the first chip so as to oppose the second pads and the second joining region respectively to the first pads and the first joining region;
electrical connection parts which electrically connect the first pads to the second pads, respectively; and
joining parts provided between the first joining region and the second joining region opposed to the first joining region to join the first chip and the second chip to each other.

2. The apparatus according to claim 1, wherein
the first joining region surrounds the MEMS device and the first pads, and
the second joining region surrounds the semiconductor device and the second pads.

3. The apparatus according to claim 2, wherein
the first pads are located between the MEMS device and the first joining region, and
the second pads are located between the semiconductor device and the second joining region.

4. The apparatus according to claim 1, wherein
the joining parts are formed of a sealing material, and
the MEMS device is sealed by using the joining parts.

5. The apparatus according to claim 4, wherein
the MEMS device comprises at least one vibration type angular velocity sensor, and
the vibration type angular velocity sensor is subjected to vacuum sealing.

6. The apparatus according to claim 5, wherein the semiconductor device comprises a detection circuit which detects an angular velocity on the basis of an output signal of the vibration type angular velocity sensor.
